(19) United States
(12) Patent Application Publication
(10) Pub. No.: US 2025/0069943 A1
(43) Pub. Date: Feb. 27, 2025

(54) HYBRID SHAFT ASSEMBLY FOR THERMAL CONTROL IN HEATED SEMICONDUCTOR PEDESTALS

(71) Applicant: WATLOW ELECTRIC MANUFACTURING COMPANY, St. Louis, MO (US)

(72) Inventors: Michael PARKER, Brentwood, CA (US); Dennis REX, Williams, OR (US); Guleid HUSSEN, San Francisco, CA (US); Jason STEPHENS, San Francisco, CA (US)

(73) Assignee: WATLOW ELECTRIC MANUFACTURING COMPANY, St. Louis, MO (US)

(21) Appl. No.: 18/940,051

(22) Filed: Nov. 7, 2024

Related U.S. Application Data
(63) Continuation of application No. PCT/US2023/066885, filed on May 11, 2023.
(60) Provisional application No. 63/341,163, filed on May 12, 2022.

(51) Int. Cl. H01L 21/687

(52) U.S. Cl. CPC H01L 21/68785; H01L 21/68757; H01L 21/68792

(57) ABSTRACT

A hybrid shaft assembly for use in controlled atmosphere chambers, such as by way of example heated pedestals for semiconductor manufacturing, includes a substrate, a hub having an upper portion and a lower portion, the upper portion being secured to the substrate with an upper joining layer, and a shaft secured to the lower portion of the hub with a lower joining layer. The shaft comprises a material having a thermal conductivity lower than a material of the hub and a material of the substrate.

### CROSS-REFERENCE TO RELATED APPLICATIONS

This application is a continuation application of International Application No. PCT/US2023/066885 filed May 11, 2023, which claims priority to and the benefit of U.S. Patent Application No. 63/341, 163, filed on May 12, 2022. The disclosures of the above applications are incorporated herein by reference in their entireties.

### FIELD

The present disclosure relates to pedestals for use in semiconductor manufacturing equipment, and more specifically to the construction of a pedestal for thermal uniformity at a wafer contact zone.

### BACKGROUND

The statements in this section merely provide background information related to the present disclosure and may not constitute prior art.

In the processing of semiconductor wafers, a pedestal is arranged within a processing chamber to support a semiconductor wafer for etching. The pedestal is often made from a ceramic material and generally includes a heater plate and a shaft secured to a lower portion of the heater plate. The shaft is generally hollow and is configured to receive a variety of electrical connections to power the heater plate and to monitor a variety of system parameters throughout the etching process.

Because semiconductor wafers must be manufactured to extremely tight tolerances, the thermal uniformity of the pedestal, and more specifically of an upper surface of the heater plate proximate the semiconductor wafer, must be tightly controlled. Accordingly, a variety of approaches have been employed to reduce the impact of heat sinks/losses during fabrication of semiconductor wafers. For example, multiple zone heaters have been used across and throughout the thickness of the heater plate, and a variety of materials have been used in the construction of the pedestal to provide more uniform temperatures during the etching process. Additional, or secondary heaters have also been provided within the shaft or on a bottom side of the heater plate, however, volume and cost constraints limit the ability to provide additional heaters to reduce thermal losses.

These challenges associated with providing thermal uniformity along upper surfaces of heated pedestals, along with other thermal loss issues within semiconductor processing equipment, are addressed by the present disclosure.

### SUMMARY

This section provides a general summary of the disclosure and is not a comprehensive disclosure of its full scope or all of its features.

The present disclosure provides a hybrid shaft assembly for use in controlled atmosphere chambers. The hybrid shaft assembly includes a substrate, a hub having an upper portion and a lower portion, the upper portion being secured to the substrate with an upper joining layer, and a shaft secured to the lower portion of the hub with a lower joining layer. The shaft comprises a material having a thermal conductivity lower than a material of the hub and a material of the substrate.

In variations of this hybrid shaft assembly, which may be implemented individually or in any combination: at least one of the upper joining layer and the lower joining layer comprise a material sputtered onto surfaces of the upper portion of the hub and the lower portion of the hub, respectively; the sputtered material defines a layer about 2 μm thick; at least one of the upper portion and the lower portion of the hub comprises a plurality of mesas; the upper portion of the hub is nominally spaced a distance apart from a lower surface of the substrate; a plurality of preformed pieces are disposed between the upper portion of the hub and the lower surface of the substrate; the preformed pieces are beads; the preformed pieces comprise a zirconia material; the lower portion of the hub is nominally spaced a distance apart from an upper surface of the shaft; a plurality of preformed pieces are disposed between the lower portion of the hub and the upper surface of the shaft; the preformed pieces comprise a zirconia material; the upper portion of the hub comprises a radial flange; the hub is integral with the substrate; at least one of the upper joining layer and the lower joining layer are formed from an aluminum foil preform; a surface area of the aluminum foil preform is less than a total surface area of an upper surface of the upper portion of the hub; a surface area of the aluminum foil preform is less than a total surface area of a lower surface of the lower portion of the hub; the surface area of the aluminum foil preform is about 50% less; the aluminum foil preform is about 0.008 in. thick; the substrate is an AIN material, the hub is an AIN material, and the shaft is an Al₂O₃ material; a secondary shaft element is secured to a lower portion of the shaft, wherein the secondary shaft element comprises a material having a thermal conductivity lower than a material of the shaft; the shaft comprises a material having a decreasing thermal conductivity from an upper portion of the shaft to a lower portion of the shaft; the thermal conductivity of the material of the shaft is continuously decreasing from the upper portion of the shaft to the lower portion of the shaft; the thermal conductivity of the material of the shaft is an order of magnitude lower than the thermal conductivity of the material of the hub and the material of the substrate; the upper joining layer and the lower joining layer provide hermetically sealed interfaces; a leak rate of the hermetically sealed interfaces is less than about 1×10⁻⁶ atm cc/sec He; a length of the shaft is about five times a length of the hub; at least one electrically functioning layer is embedded within the substrate; the at least one electrically functioning element is selected from the group consisting of a heater, an RF antenna, and a clamping electrode; and the upper portion is a upper flanged portion, each of the upper flanged portion and the lower portion define a plurality of mesas and comprise a sputtered layer of aluminum, and the upper and lower joining layers comprise an aluminum braze material having 99.99% aluminum content.

Further areas of applicability will become apparent from the description provided herein. It should be understood that the description and specific examples are intended for purposes of illustration only and are not intended to limit the scope of the present disclosure.

### DRAWINGS

In order that the disclosure may be well understood, there will now be described various forms thereof, given by way of example, reference being made to the accompanying drawings, in which:

FIG. 1 is a top perspective view of a hybrid shaft assembly for use in controlled atmosphere chambers, such as by way of example heated pedestals for semiconductor manufacturing, constructed according to the teachings of the present disclosure;

FIG. 2 is a bottom perspective view of the hybrid shaft assembly of FIG. 1;

FIG. 3 is a top exploded perspective of the hybrid shaft assembly of FIG. 1;

FIG. 4 is a bottom exploded perspective of the hybrid shaft assembly of FIG. 1;

FIG. 5 is a side view of the hybrid shaft assembly of FIG. 1;

FIG. 6 is a side cross-sectional view of the hybrid shaft assembly of FIG. 1, taken along line 6-6 of FIG. 5;

FIG. 7 is a top perspective view of an upper portion of shaft of the hybrid shaft assembly constructed in accordance with the teachings of the present disclosure;

FIG. 8 is a top view of a hub and an upper aluminum preform constructed in accordance with the teachings of the present disclosure;

FIG. 9 is a bottom perspective view of the hub and a lower aluminum preform constructed in accordance with the teachings of the present disclosure;

FIG. 10 is a top perspective view of the hub having a sputtered material and constructed in accordance with the teachings of the present disclosure;

FIG. 11 is a bottom perspective view of the hub having a sputtered material and constructed in accordance with the teachings of the present disclosure;

FIG. 12 is a side view of another form of a hybrid shaft assembly constructed according to the teachings of the present disclosure; and

FIG. 13 is a manufacturing flow diagram of a method of joining a substrate, the hub, and the shaft in accordance with the teachings of the present disclosure.

The drawings described herein are for illustration purposes only and are not intended to limit the scope of the present disclosure in any way.

### DETAILED DESCRIPTION

The following description is merely exemplary in nature and is not intended to limit the present disclosure, application, or uses. It should be understood that throughout the drawings, corresponding reference numerals indicate like or corresponding parts and features.

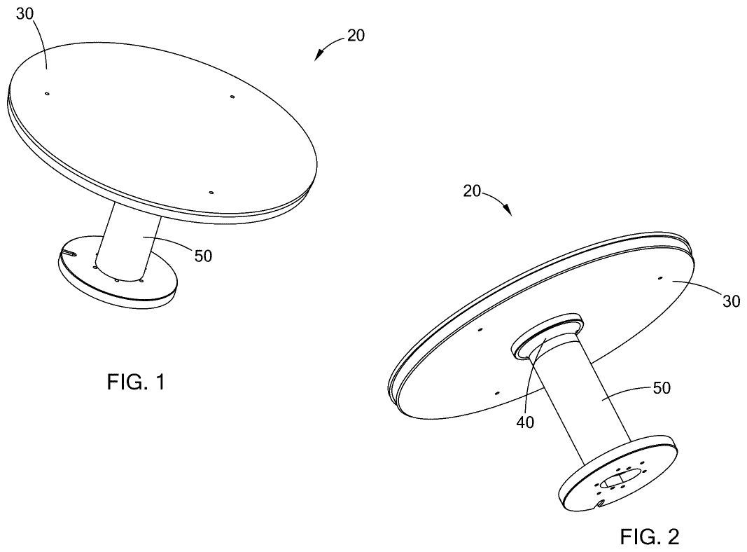

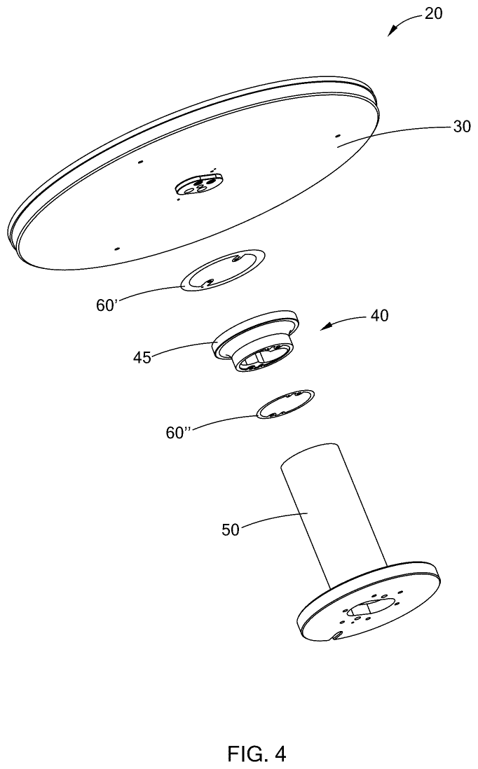

Referring to FIGS. 1-4, a hybrid shaft assembly for use in controlled atmosphere chambers is illustrated and generally indicated by reference numeral 20. In this form, the hybrid shaft assembly 20 is in the form of a pedestal (e.g., a heated pedestal) for use in semiconductor manufacturing. However, the application to semiconductor manufacturing should not be construed as limiting the scope of the present disclosure.

The hybrid shaft assembly 20 generally comprises a substrate 30, a hub 40, and a shaft 50. The substrate 30 in one form is a ceramic material, such as AIN (aluminum nitride) by way of example and contains one or more electrically functioning elements used in the semiconductor manufacturing process. Such electrically functioning elements (not shown for purposes of clarity) within the substrate 30 may include by way of example a heater (having one or more zones), an RF antenna (one or more electrically independent/isolated sections), and/or a clamping electrode, among others. Such electrically functioning elements are described in greater detail in U.S. Pat. No. 10,287,215, which is commonly owned with the present application and the contents of which are incorporated herein by reference in their entirety.

Advantageously, the shaft 50 comprises a material having a thermal conductivity lower than a material of the hub 40 and a material of the substrate 30. For example, in one form the substrate 30 is an AlN material (about 150-250 W/(m·°K)), the hub 40 is also an AlN material, and the shaft 50 is an Al₂O₃ (about 30 W/(m·°K)) material. Accordingly, in this form, the thermal conductivity of the material of the shaft 50 is an order of magnitude lower than the thermal conductivity of the material of the hub 40 and the material of the substrate 30. As a result, the hybrid shaft assembly 20 has lower heat loss through the shaft 50 and thus improves temperature uniformity in a wafer contact zone (not shown) during processing operations within the controlled atmosphere chamber.

The hub 40 has an upper portion 42 that is joined to the substrate 30 with an upper joining layer (described in greater detail below) and a lower portion 44 that is joined to the shaft 50 with a lower joining layer (described in greater detail below). The upper portion 42 of the hub 40 comprises a radial flange 45 as shown. The radial flange 45 generally provides an increased area for the upper joining layer to bond to and secure the substrate 30. However, in one form, the hub 40 may be integral with the substrate 30 and formed as a single piece (not shown) in one form of the present disclosure, thereby eliminating the upper joining layer.

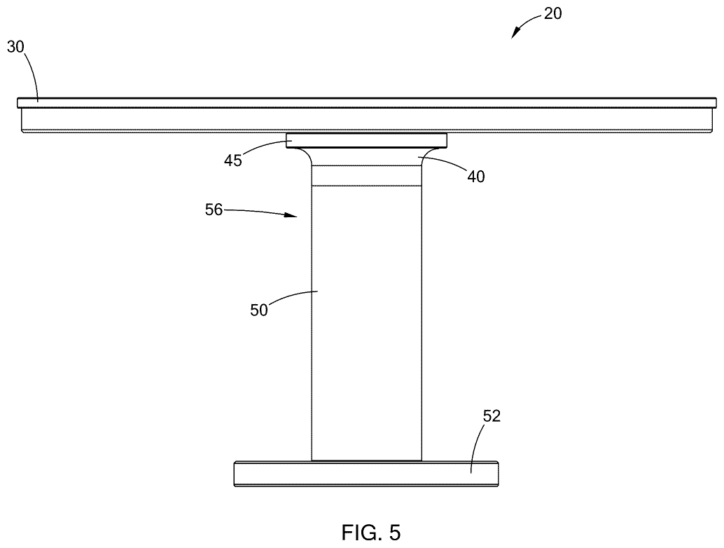

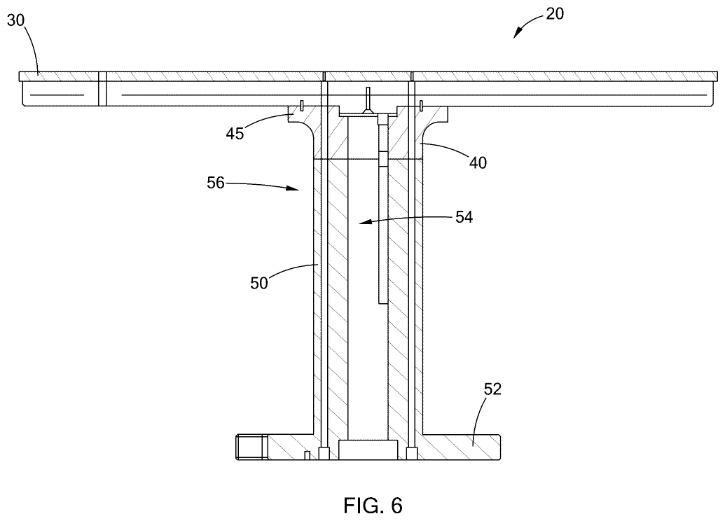

Referring also to FIGS. 5-7, the shaft 50 includes a base 52, which in this form is integrally formed with the shaft 50 as one part. The shaft 50 is generally hollow and includes a bore 54 extending therethrough. The bore 54 accommodates a variety of electrical components and connections, which are not illustrated and described herein for purposes of clarity. The shaft 50 further defines an upper portion 56, which is configured to be joined to the hub 40 as described in greater detail below. Further, a length of the shaft 50 in one form of the present disclosure is about five (5) times a length of the hub 40.

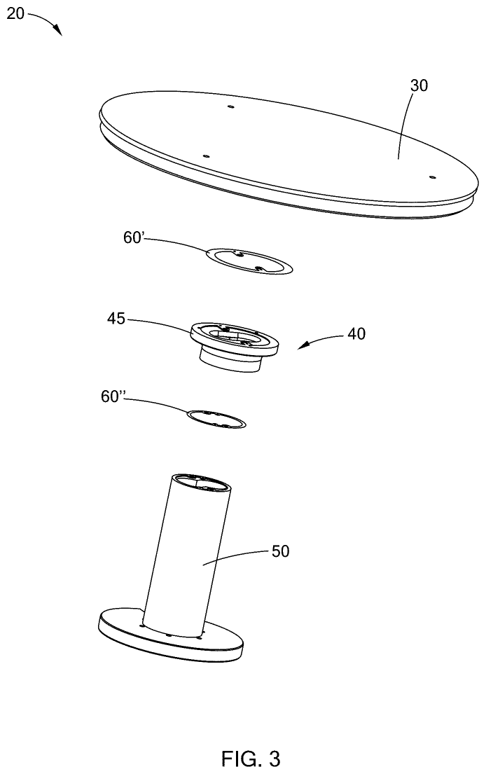

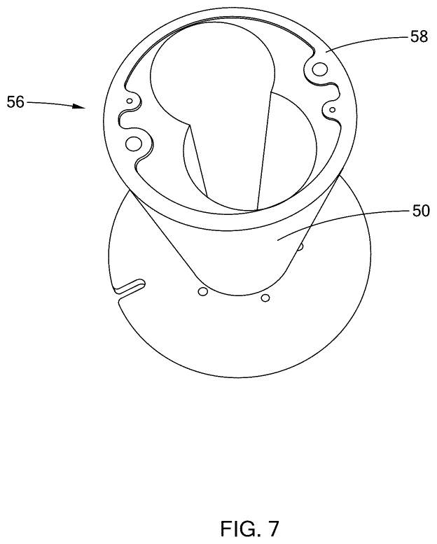

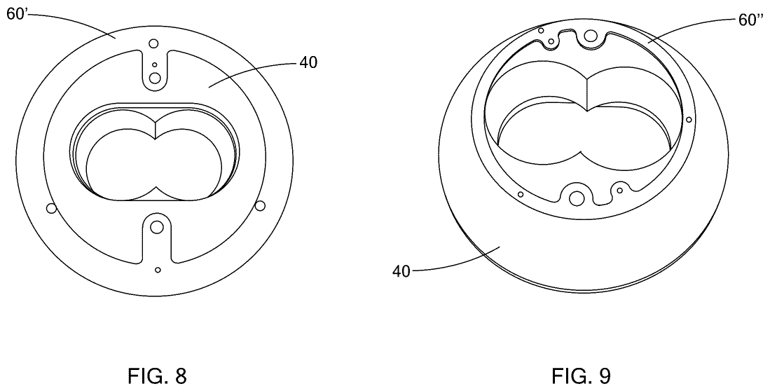

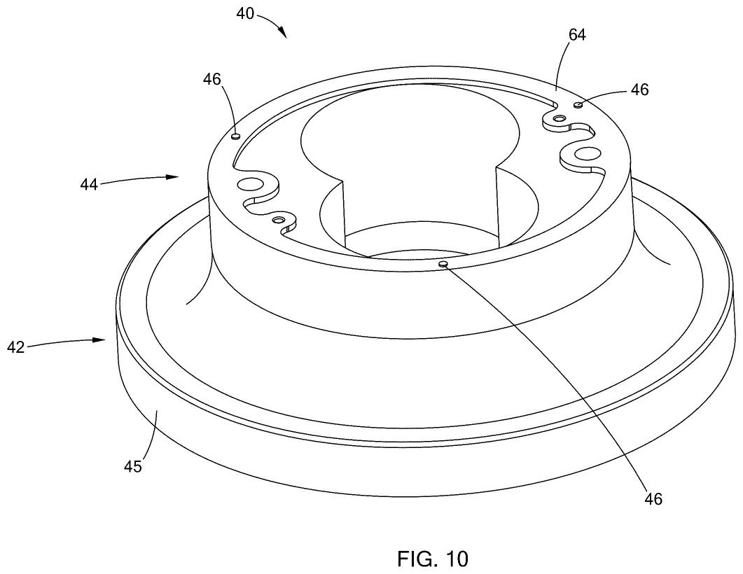

Referring now FIGS. 7-11, and also FIG. 3, the upper and lower joining layers are now illustrated and described in greater detail. In one form, at least one of the upper joining layer and the lower joining layer are formed from a foil preform, which in this form is aluminum. Further, the aluminum in one form has a relatively high purity (at least about 99.99% pure Al). In the illustrated variation, an upper aluminum preform 60′ is disposed between the substrate 30 and the hub 40, and a lower aluminum preform 60″ is disposed between the hub 40 and the shaft. The aluminum foil preforms 60′/60″ are shaped to generally follow the surface profile of the upper and lower surfaces of the hub 40, respectively, and also include various openings to accommodate the electrical components/connections as referred to above in addition to alignment features. In one form, a surface area of the upper aluminum foil preform 60′ is less than a total surface area of an upper surface of the upper portion 42 of the hub 40. In still another form, a surface area of the lower aluminum foil preform 60″ is less than a total surface area of a lower surface of the lower portion 44 of the hub 40. By way of example, the surface area of the aluminum foil preform 60′/60″ is about 50% less in one form of the present disclosure. With these reduced surface areas, the CTE (coefficient of thermal expansion) mismatch between the materials of the hub 40 and the adjacent shaft 50 and substrate 30 are mitigated to reduce thermal stresses. Further, in the illustrated form, the upper and lower aluminum foil preforms 60′/60″ are about 0.008 in. thick. It should be understood, however, that materials other than aluminum and different thicknesses may be employed while remaining within the scope of the present disclosure.

The upper joining layer and the lower joining layer as illustrated and described herein provide hermetically sealed interfaces between the substrate 30 and the hub 40, and also between the hub 40 and the shaft 50. Generally, the seal is hermetic to meet application requirements within the processing chamber. The hermeticity, or leak rate, in one form is less than about 1×10⁻⁶ atm cc/sec (standard cubic centimeters per second) He. In another form, the leak rate is less than about 1×10⁻⁷ atm cc/sec He, and still in another form, the leak rate is less than about 1×10⁻⁹ atm cc/sec He.

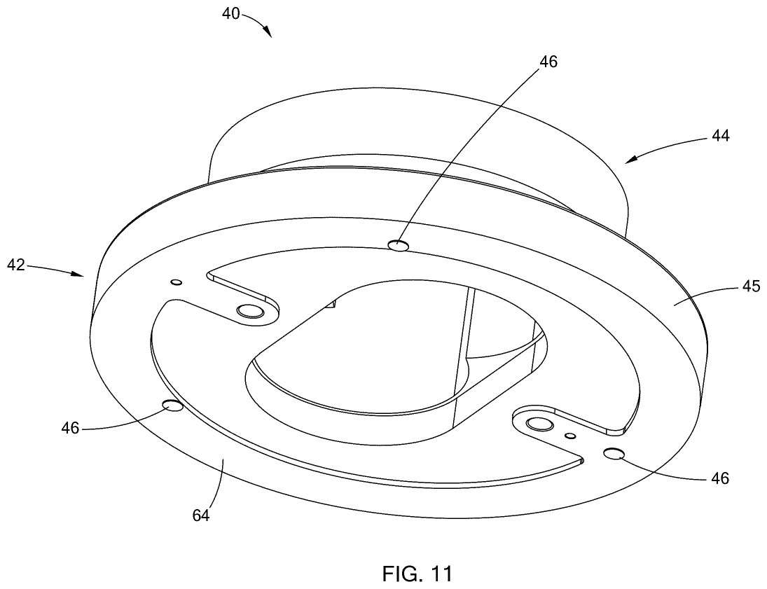

With specific reference to FIGS. 10 and 11, in addition to the aluminum foil preforms 60′/60″ as set forth above, at least one of the upper joining layer and the lower joining layer further comprise a material 64 sputtered onto surfaces of the upper portion 42 of the hub 40 and the lower portion 44 of the hub 40, respectively. The sputtered material 64 in one form is an aluminum material with a relatively high purity (at least about 99.99% pure Al) and defines a layer about 2 μm thick. The sputtered material 64 is provided in order to promote wetting of the aluminum preforms 60′/60″ into the substrate 30 and shaft 50, respectively.

As further shown, the surfaces of the upper portion 42 and the lower portion 44 of the hub 40 include a plurality of mesas 46. The mesas 46 are provided in order to control a bond line thickness, or to provide a consistent gap between the hub 40 and the shaft 50 and also between the hub 40 and the substrate 30. In this form, a total of three (3) mesas 46 are evenly spaced around a circumference of the upper and lower surfaces of the hub 40. However, it should be understood that fewer or greater than three (3) mesas 46, in a variety of spacing configurations, may be employed while remaining within the scope of the present disclosure. In one form, the mesas 46 are about 0.0055 in.-0.0075 in. tall and about 0.100 in. in diameter. The mesas 46 may also take on another geometry other than round/cylindrical while remaining within the scope of the present disclosure. In one form, the mesas 46 are formed by selective removal of material of the hub 40.

As shown in FIG. 7, the upper portion 56 of the shaft 50 comprises a raised area 58 that is shaped to match the shape of the lower aluminum preform 60″. This raised area also facilitates a reduced surface area for bonding to reduce the impact of CTE mismatch as set forth above.

With the upper joining layer as illustrated and described herein, the upper portion 42 of the hub 40 is nominally spaced a distance apart from a lower surface of the substrate 30. Similarly, with the lower joining layer, the lower portion of the hub 40 is nominally spaced a distance apart from an upper surface of the shaft 50. In one form, rather than implementing mesas, a plurality of preformed pieces (not shown) are disposed between the upper portion of the hub 40 and the lower surface of the substrate 30, and/or between the lower portion of the hub 40 and the upper surface of the shaft 50. The preformed pieces in one form are in the shape of beads but may also take on other shapes while remaining within the scope of the present disclosure. Further, the preformed pieces may be any of a variety of materials such as aluminum or zirconia, among others.

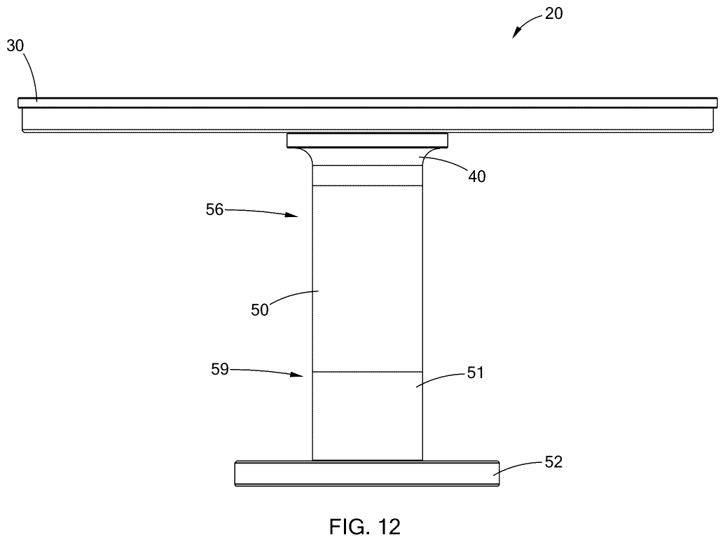

Referring now to FIG. 12, another form of a hybrid shaft assembly 20 comprises a secondary shaft element 51 secured to a lower portion 59 of the shaft 50. The secondary shaft element 51 may be bonded to the shaft 50 and the base 52 using any of the methods described herein, among others. The secondary shaft element 51 comprises a material having a thermal conductivity lower than a material of the shaft 50 and thus provides an additional means to reduce heat loss through the shaft 50. For example, the secondary shaft element 51 may be a zirconia material.

In yet another form, the shaft 50 may be constructed of a variable composition material such that it has a decreasing thermal conductivity from the upper portion 56 of the shaft 50 to the lower portion 59 of the shaft 50. The thermal conductivity in one form is continuously decreasing from the upper portion 56 of the shaft 50 to the lower portion 59 of the shaft 50. In another form, the thermal conductivity is decreasing in zones from the upper portion 56 of the shaft 50 to the lower portion 59 of the shaft 50. In still another form, the decreasing thermal conductivity may be achieved with varying the geometry of the shaft 50, for example, by having a larger diameter or outer periphery at the upper portion 56 and a smaller diameter or outer periphery at the lower portion 59. This variable geometry may be continuous or in discrete zones, and the variable geometry may also be combined with the variable composition material while remaining within the scope of the present disclosure.

The hybrid shaft assembly may be joined by a variety of methods while remaining within the scope of the present disclosure, including but not limited to, brazing, and solid-state/diffusion bonding, or transient liquid phase bonding. As used herein, it should be understood that brazing refers to a method in which the temperature of the material of the joining layers exceeds its liquidus temperature. “Solid-state” bonding means that a temperature of the material of the joining layers remains below its liquidus temperature throughout the application of heat and pressure during the bonding process. Solid-state bonding may also be referred to as diffusion bonding, however, the teachings of the present disclosure do not necessarily require that the material of each joining layer diffuse into the substrate, hub, or shaft material. Further, it should be understood that “liquidus” as used herein should be construed to include transient liquid phase bonding.

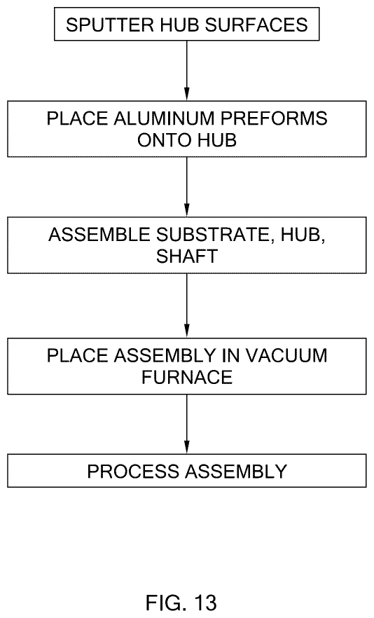

Referring now to FIG. 13, and also to FIGS. 3, 10, and 11, one method of forming the hybrid shaft assembly 20 is illustrated in greater detail. First, the material 64 is sputtered onto surfaces of the upper portion 42 of the hub 40 and the lower portion 44 of the hub 40. Next, the aluminum preforms 60′/60″ are placed onto the sputtered surfaces of the hub. The substrate 30, hub 40, and shaft 50 are then assembled together and placed into a vacuum furnace, with the substrate 30 on the bottom and the base 52 of the shaft 50 at the top. In one form, a weight, which may be about 2 lbs, is placed onto the base 52 of the shaft 50 to stabilize the assembly. The hybrid shaft assembly 20 is processed in the vacuum furnace for a predetermined time, temperature, and pressure. In one form, the temperature is about 850° C., the dwell time is about 20 minutes, and the pressure is less than about 1×10⁻⁶ psi. It should be understood, however, that the time, temperature, and pressure will vary as a function of the materials and geometry of the hybrid shaft assembly 20, and thus these processing values are merely exemplary and not intended to be limiting of the present disclosure.

Unless otherwise expressly indicated herein, all numerical values indicating mechanical/thermal properties, compositional percentages, dimensions and/or tolerances, or other characteristics are to be understood as modified by the word “about” or “approximately” in describing the scope of the present disclosure. This modification is desired for various reasons including industrial practice, material, manufacturing, and assembly tolerances, and testing capability.

As used herein, the phrase at least one of A, B, and C should be construed to mean a logical (A OR B OR C), using a non-exclusive logical OR, and should not be construed to mean “at least one of A, at least one of B, and at least one of C.”

The description of the disclosure is merely exemplary in nature and, thus, variations that do not depart from the substance of the disclosure are intended to be within the scope of the disclosure. For example, in some applications, the thermal conductivity may instead be controlled in an opposite manner such that the thermal conductivity is higher at the lower portion of the shaft rather than lower. Further, the thermal conductivity may be varied in any geometric dimension and in any positive or negative direction using the teachings herein. Such variations are not to be regarded as a departure from the spirit and scope of the disclosure.

What is claimed is:

1. A hybrid shaft assembly for use in controlled atmosphere chambers, the hybrid shaft assembly comprising:
a substrate;
a hub having an upper portion and a lower portion, the upper portion being secured to the substrate with an upper joining layer; and
a shaft secured to the lower portion of the hub with a lower joining layer,
wherein the shaft comprises a material having a thermal conductivity lower than a material of the hub and a material of the substrate.

2. The hybrid shaft assembly according to claim 1, wherein at least one of the upper joining layer and the lower joining layer comprise a material sputtered onto surfaces of the upper portion of the hub and the lower portion of the hub, respectively.

3. The hybrid shaft assembly according to claim 2, wherein the sputtered material defines a layer about 2 μm thick.

4. The hybrid shaft assembly according to claim 1, wherein at least one of the upper portion and the lower portion of the hub comprises a plurality of mesas.

5. The hybrid shaft assembly according to claim 1, wherein the upper portion of the hub is nominally spaced a distance apart from a lower surface of the substrate.

6. The hybrid shaft assembly according to claim 5, further comprising a plurality of preformed pieces disposed between the upper portion of the hub and the lower surface of the substrate.

7. The hybrid shaft assembly according to claim 6, wherein the preformed pieces comprise a zirconia material.

8. The hybrid shaft assembly according to claim 1, wherein the lower portion of the hub is nominally spaced a distance apart from an upper surface of the shaft.

9. The hybrid shaft assembly according to claim 8, further comprising a plurality of preformed pieces disposed between the lower portion of the hub and the upper surface of the shaft.

10. The hybrid shaft assembly according to claim 9, wherein the preformed pieces comprise a zirconia material.

11. The hybrid shaft assembly according to claim 1, wherein the upper portion of the hub comprises a radial flange.

12. The hybrid shaft assembly according to claim 1, wherein the hub is integral with the substrate.

13. The hybrid shaft assembly according to claim 1, wherein at least one of the upper joining layer and the lower joining layer are formed from an aluminum foil preform.

14. The hybrid shaft assembly according to claim 13, wherein a surface area of the aluminum foil preform is less than a total surface area of an upper surface of the upper portion of the hub.

15. The hybrid shaft assembly according to claim 14, wherein the surface area of the aluminum foil preform is about 50% less.

16. The hybrid shaft assembly according to claim 13, wherein a surface area of the aluminum foil preform is less than a total surface area of a lower surface of the lower portion of the hub.

17. The hybrid shaft assembly according to claim 13, wherein the aluminum foil preform is about 0.008 in. thick.

18. The hybrid shaft assembly according to claim 1, wherein the substrate is an AIN material, the hub is an AIN material, and the shaft is an Al₂O₃ material.

19. The hybrid shaft assembly according to claim 1, further comprising a secondary shaft element secured to a lower portion of the shaft, wherein the secondary shaft element comprises a material having a thermal conductivity lower than a material of the shaft.

20. The hybrid shaft assembly according to claim 1, wherein the shaft comprises a material having a decreasing thermal conductivity from an upper portion of the shaft to a lower portion of the shaft.

21. The hybrid shaft assembly according to claim 20, wherein the thermal conductivity of the material of the shaft is continuously decreasing from the upper portion of the shaft to the lower portion of the shaft.

22. The hybrid shaft assembly according to claim 1, wherein the thermal conductivity of the material of the shaft is an order of magnitude lower than the thermal conductivity of the material of the hub and the material of the substrate.

23. The hybrid shaft assembly according to claim 1, wherein the upper joining layer and the lower joining layer provide hermetically sealed interfaces.

24. The hybrid shaft assembly according to claim 23, wherein a leak rate of the hermetically sealed interfaces is less than about 1×10⁻⁶ atm cc/sec He.

25. The hybrid shaft assembly according to claim 1, wherein a length of the shaft is about five times a length of the hub.

26. The hybrid shaft assembly according to claim 1, further comprising at least one electrically functioning layer embedded within the substrate.

27. The hybrid shaft assembly according to claim 26, wherein the at least one electrically functioning element is selected from the group consisting of a heater, an RF antenna, and a clamping electrode.

28. The hybrid shaft assembly according to claim 1, wherein
the upper portion is a flanged upper portion,
each of the upper flanged portion and the lower portion define a plurality of mesas, and comprise a sputtered layer of aluminum, and
the upper joining layer and the lower joining layer each comprise an aluminum braze material having 99.99% aluminum content, the aluminum braze material being formed from an aluminum foil preform.
